(19) United States
(12) Patent Application Publication
(10) Pub. No.: US 2025/0383370 A1
(43) Pub. Date: Dec. 18, 2025

(54) SOCKET

(71) Applicant: YOKOWO CO., LTD., Tokyo (JP)

(72) Inventor: Hiroshi KATO, Tomioka-shi, Gunma (JP)

(73) Assignee: YOKOWO CO., LTD., Tokyo (JP)

(21) Appl. No.: 19/108,746

(22) PCT Filed: Sep. 5, 2023
(86) PCT No.: PCT/JP2023/032343

§ 371 Date: Mar. 5, 2025

(30) Foreign Application Priority Data
Sep. 6, 2022 (JP) 2022-141603

(51) Int. Cl. G01R 1/067; G01R 1/04

(52) U.S. Cl. CPC G01R 1/06716; G01R 1/0408

(57) ABSTRACT

A socket including an elastic probe and a conductor through which the probe extends, in which the conductor has a receiving portion for receiving the probe.

### TECHNICAL FIELD

The present invention relates to a socket.

### BACKGROUND ART

In recent years, various sockets used for objects under inspection such as integrated circuits (IC) have been developed. For example, as described in Patent Document 1, the socket includes a probe, a metal housing, an upper resin plate overlapping the upper surface of the housing, and a lower resin plate overlapping the lower surface of the housing. The probe has a barrel extending through the housing, an upper plunger extending through the upper resin plate, and a lower plunger extending through the lower resin plate. The housing defines a through hole through which the barrel extends. The value of the diameter of the through hole of the housing is greater than the value of the diameter of the barrel. The value of the diameter of the through hole of the housing is greater than the value of the diameter of the barrel results in configuration of a coaxial probe.

### RELATED DOCUMENT

### Patent Document

Patent Document 1: Japanese Unexamined Patent Publication No. 2019-178947

### SUMMARY OF THE INVENTION

### Technical Problem

In the socket disclosed in Patent Document 1, for example, preload may be generated by pushing the lower end portion of the lower plunger against the inspection substrate while the upper end portion of the upper plunger is not subjected to an external force. Specifically, the spring provided in the space inside the barrel is compressed by the force received by the upper end portion of the barrel from the upper resin plate and the force received by the lower end portion of the lower plunger from the inspection substrate. The preload is generated as the spring is compressed. The barrel and the upper plunger are biased upward by the preload. When the barrel and the upper plunger are biased upward by the preload, a force received by the upper resin plate from the upper end portion of the barrel may cause warping of the upper resin plate. The warping of the upper resin plate may cause a less compression of the spring provided in the space inside the barrel by the amount of warping of the upper resin plate. The less compression of the spring may make it difficult to stabilize the electrical contact between the lower plunger and the inspection substrate. As a result, it may be difficult to stably generate the preload.

An example of the objects of the present invention is to stably generate a preload. Other objects of the present invention will become apparent from the description of the present specification.

### Solution to Problem

An aspect of the present invention is a socket including:

an elastic probe; and

a conductor through which the probe extends,

in which the conductor has a receiving portion for receiving the probe.

According to the aspect described above of the present invention, the preload can be stably generated.

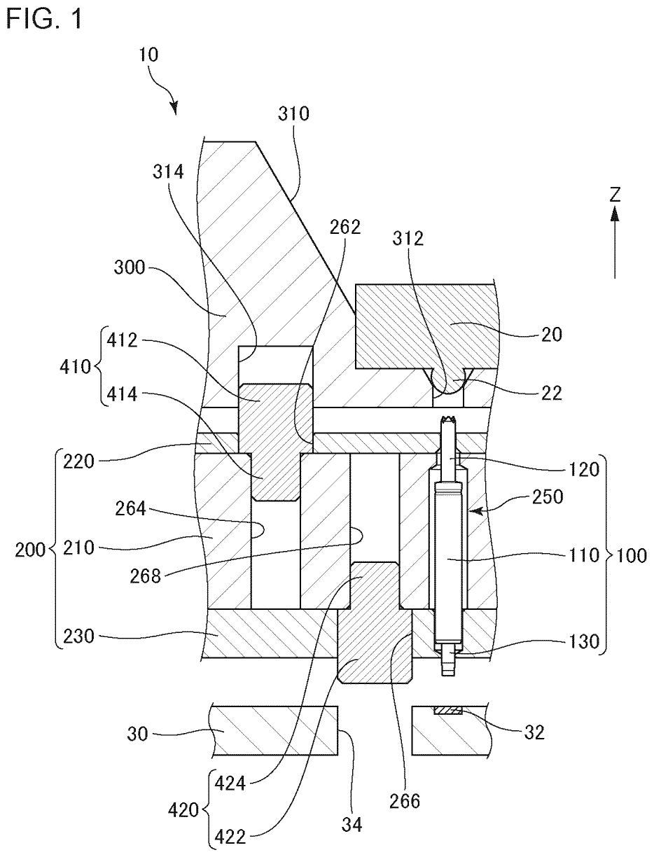

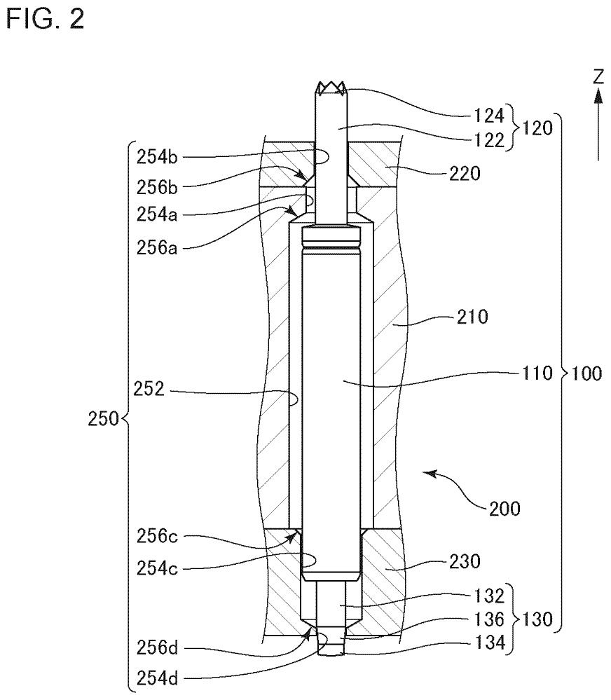

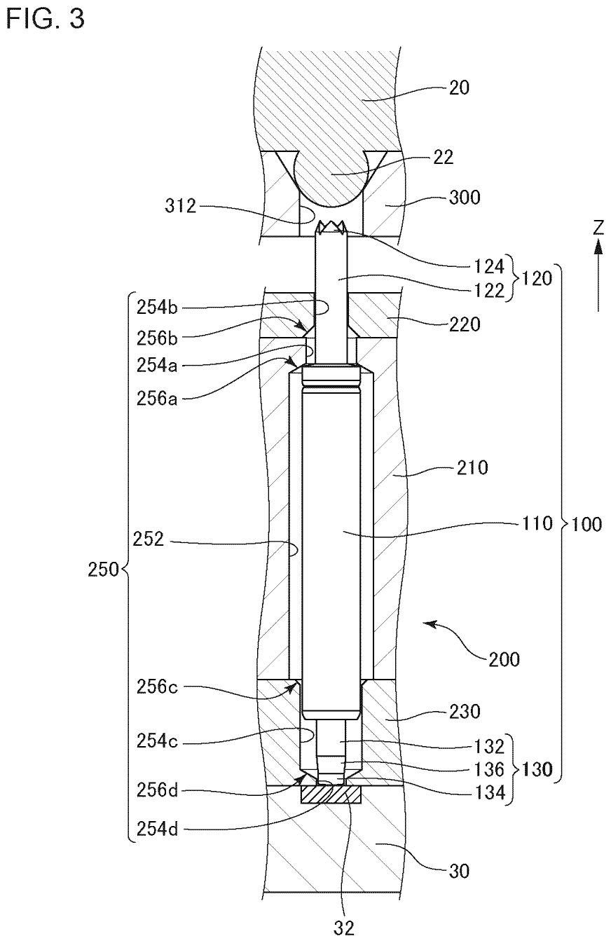

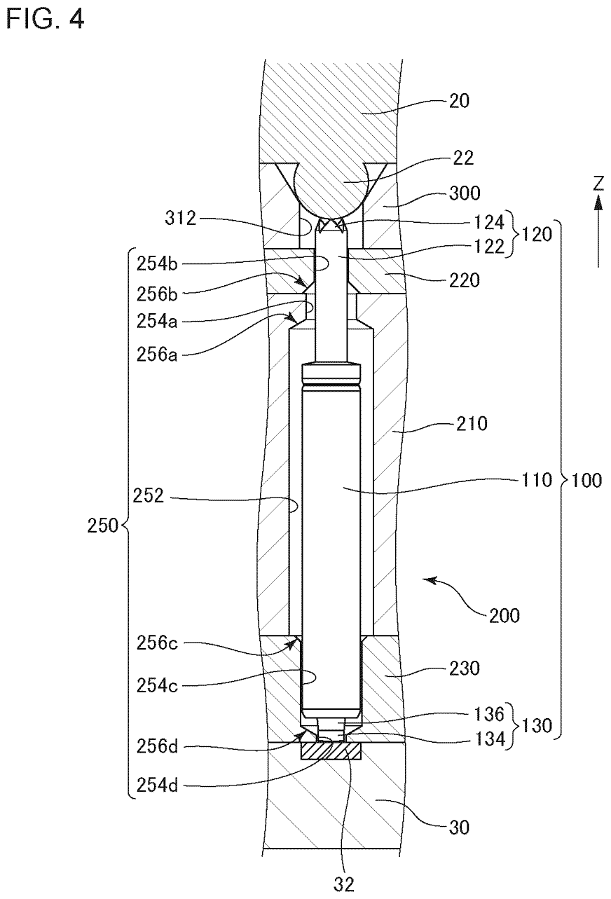

### BRIEF DESCRIPTION OF THE DRAWINGS

[FIG. 1] A cross-sectional view showing a socket according to an embodiment.

[FIG. 2] An enlarged cross-sectional view of a probe according to the embodiment and a periphery thereof.

[FIG. 3] A view for explaining an example of a method of electrically connecting an object under inspection and an inspection substrate to each other via a socket according to the embodiment.

[FIG. 4] A view for explaining an example of a method of electrically connecting an object under inspection and an inspection substrate to each other via a socket according to the embodiment.

### DESCRIPTION OF EMBODIMENTS

Hereinafter, an embodiment of the present invention will be described with reference to the drawings. In all the drawings, the same constitutional components are denoted by the same reference signs, and description thereof will not be repeated as appropriate.

For explanation of the direction, the letter Z is used for definition. The Z direction is a direction substantially parallel to the vertical direction. In the embodiment, the Z direction is described as the vertical direction. In each drawing, a direction indicated by an arrow of the Z-axis is defined as an upward direction. Hereinafter, a direction perpendicular to the Z direction will be referred to as a horizontal direction, as necessary.

FIG. 1 is a cross-sectional view showing a socket 10 according to an embodiment. FIG. 2 is an enlarged cross-sectional view of the probe 100 according to the embodiment and the periphery thereof.

The socket 10 will be described with reference to FIG. 1 and, as necessary, FIG. 2.

The socket 10 according to the embodiment includes a probe 100, a support body 200, a floating plate 300, an upper guide pin 410, and a lower guide pin 420. In the embodiment, the object under inspection 20 is inspected by the inspection substrate 30 using the socket 10. The object under inspection 20 is, for example, an integrated circuit (IC). The inspection substrate 30 is, for example, a printed circuit board (PCB).

The probe 100 is elastic and has a barrel 110, a first plunger 120, and a second plunger 130. The first plunger 120 includes a first column portion 122 and a first distal end portion 124. The first distal end portion 124 is provided at the upper end portion of the first column portion 122. The second plunger 130 includes a second column portion 132, a second distal end portion 134, and a tapered portion 136. The second distal end portion 134 is provided at the lower end portion of the second column portion 132 via the tapered portion 136. The value of the diameter of the tapered portion 136 in the horizontal direction decreases from the upper side toward the lower side. The value of the diameter of the second distal end portion 134 in the horizontal direction is less than the value of the diameter of the second column portion 132 in the horizontal direction.

The barrel 110 extends substantially parallel to the Z direction. The barrel 110 has a hollow structure. A spring not illustrated is provided in a space inside the barrel 110.

The first plunger 120 is provided at the upper end portion of the barrel 110. In the embodiment, the barrel 110 and the first plunger 120 are integrated. In other words, the first plunger 120 is fixed to the barrel 110 in the Z direction. The barrel 110 and the first plunger 120 are biased upward by the unillustrated spring provided in the space inside the barrel 110. As the first plunger 120 is biased upward by the spring, the barrel 110 and the first plunger 120 are biased in a direction away from the second plunger 130. The probe 100 is a single ended probe. The probe 100, which is a single ended probe, can reduce the electrical resistance as compared when the probe is a double ended probe, that is, when the first plunger is movable in the Z direction with respect to the barrel. The probe may be a double ended probe, however, when the insulator ring is used.

The second plunger 130 is provided at the lower end portion of the barrel 110. The second plunger 130 is movable in the Z direction with respect to the barrel 110. The second plunger 130 is biased downward by the unillustrated spring provided in the space inside the barrel 110. As the second plunger 130 is biased downward by the spring, the second plunger 130 is biased in a direction away from the first plunger 120.

In the inspection using the socket 10, the first distal end portion 124 of the first plunger 120 is electrically connected to each first electrode 22 disposed on the lower surface of the object under inspection 20. The second distal end portion 134 of the second plunger 130 is electrically connected to the second electrode 32 disposed on the upper surface of the inspection substrate 30. As the first plunger 120 and the second plunger 130 are electrically connected to the first electrode 22 and the second electrode 32 respectively, the first electrode 22 and the second electrode 32 are electrically connected to each other via the probe 100.

In the states shown in FIGS. 1 and 2, the first distal end portion 124 of the first plunger 120 and the second distal end portion 134 of the second plunger 130 are released. That is, the first distal end portion 124 is not subjected to an external force from the upper side by the first electrode 22. The second distal end portion 134 is not subjected to an external force from the lower side by the second electrode 32.

Hereinafter, unless otherwise specified, the probe 100 is a single ended probe.

The support body 200 has a pin block 210, an insulate plate 220, and a pin plate 230. The support body 200 supports the probe 100 substantially parallel to the Z direction.

The pin block 210 is made of metal. That is, the pin block 210 is a conductor. In the embodiment, the pin block 210 is made of brass. The pin block 210 is made of a material having relatively high rigidity. Specifically, the rigidity of the pin block 210 is greater than the rigidity of the insulate plate 220.

The insulate plate 220 overlaps the upper surface of the pin block 210 in the Z direction. The insulate plate 220 is made of a resin. That is, the insulate plate 220 is an insulator. The insulate plate 220 is made of, for example, polyether ether ketone (PEEK). The thickness of the insulate plate 220 in the Z direction is less than the thickness of the pin block 210 in the Z direction.

The pin plate 230 overlaps the lower surface of the pin block 210 in the Z direction. The pin plate 230 is made of a resin. That is, the pin plate 230 is an insulator. The pin plate 230 is made of, for example, polyether ether ketone (PEEK). The thickness of the pin plate 230 in the Z direction is less than the thickness of the pin block 210 in the Z direction.

The support body 200 defines the through hole 250. The probe 100 extends through the through hole 250 substantially parallel to the Z direction. As shown in FIG. 2, the through hole 250 includes a center straight hole 252, a first upper straight hole 254a, a second upper straight hole 254b, a first lower straight hole 254c, a second lower straight hole 254d, a first upper tapered hole 256a, a second upper tapered hole 256b, a first lower tapered hole 256c, and a second lower tapered hole 256d.

The center straight hole 252 extends through the pin block 210 substantially in parallel in the Z direction except for the upper end portion of the pin block 210. The value of the diameter of the center straight hole 252 in the horizontal direction is substantially constant regardless of the position in the Z direction.

The first upper straight hole 254a extends through the upper end portion of the pin block 210 substantially parallel to the Z direction. The value of the diameter of the first upper straight hole 254a in the horizontal direction is substantially constant regardless of the position in the Z direction. The lower end of the first upper straight hole 254a and the upper end of the center straight hole 252 communicate with each other through the first upper tapered hole 256a. The first upper tapered hole 256a is provided in a portion of the pin block 210 between the center straight hole 252 and the first upper straight hole 254a. The value of the diameter of the first upper tapered hole 256a in the horizontal direction decreases from the lower side toward the upper side.

The second upper straight hole 254b extends through the insulate plate 220 substantially parallel to the Z direction except for the lower end portion of the insulate plate 220. The value of the diameter of the second upper straight hole 254b in the horizontal direction is substantially constant regardless of the position in the Z direction. The lower end of the second upper straight hole 254b and the upper end of the first upper straight hole 254a communicate with each other through the second upper tapered hole 256b. The second upper tapered hole 256b is provided at the lower end portion of the insulate plate 220. The value of the diameter of the second upper tapered hole 256b in the horizontal direction decreases from the lower side toward the upper side.

The first lower straight hole 254c extends through the pin plate 230 substantially parallel to the Z direction except for the lower end portion of the pin plate 230 and the first lower tapered hole 256c. The value of the diameter of the first lower straight hole 254c in the horizontal direction is substantially constant regardless of the position in the Z direction. The upper end of the first lower straight hole 254c and the lower end of the center straight hole 252 communicate with each other through the first lower tapered hole 256c. The first lower tapered hole 256c is provided at the upper end portion of the pin plate 230. The value of the diameter of the first lower tapered hole 256c in the horizontal direction decreases from the upper side toward the lower side.

The second lower straight hole 254d extends through the lower end portion of the pin plate 230 substantially parallel to the Z direction. The value of the diameter of the second lower straight hole 254d in the horizontal direction is substantially constant regardless of the position in the Z direction. The upper end of the second lower straight hole 254d and the lower end of the first lower straight hole 254c communicate with each other through the second lower tapered hole 256d. The second lower tapered hole 256d is provided in a portion of the pin plate 230 between the first lower straight hole 254c and the second lower straight hole 254d. The value of the diameter of the second lower tapered hole 256d in the horizontal direction decreases from the upper side toward the lower side.

The barrel 110 is inserted into the center straight hole 252 and the first lower straight hole 254c substantially in parallel with the Z direction. The value of the diameter of the barrel 110 in the horizontal direction is less than the value of the diameter of the center straight hole 252 in the horizontal direction and less than the value of the diameter of the first lower straight hole 254c in the horizontal direction. As the value of the diameter of the barrel 110 in the horizontal direction is less than the value of the diameter of the center straight hole 252 in the horizontal direction and less than the value of the diameter of the first lower straight hole 254c in the horizontal direction, the barrel 110 is slidable in the Z direction substantially in parallel in the center straight hole 252 and the first lower straight hole 254c. A hollow gap is provided between the outer side surface of the barrel 110 and the inner side surface of the center straight hole 252. The coaxial probe can be configured by the hollow gap provided between the outer side surface of the barrel 110 and the inner side surface of the center straight hole 252. The value of the diameter of the barrel 110 in the horizontal direction is equal to or greater than the value of the diameter of the first upper straight hole 254a in the horizontal direction. As the value of the diameter of the barrel 110 in the horizontal direction is equal to or greater than the value of the diameter of the first upper straight hole 254a in the horizontal direction, the barrel 110 can be prevented from exiting upward from the first upper straight hole 254a. The value of the diameter of the barrel 110 in the horizontal direction is equal to or greater than the value of the diameter of the second lower straight hole 254d in the horizontal direction. As the value of the barrel 110 in the horizontal direction is equal to or greater than the value of the diameter of the second lower straight hole 254d in the horizontal direction, the barrel 110 can be prevented from exiting downward from the second lower straight hole 254d.

The first column portion 122 of the first plunger 120 is inserted into the first upper straight hole 254a and the second upper straight hole 254b substantially in parallel with the Z direction. The value of the diameter of the first column portion 122 in the horizontal direction is less than the value of the diameter of the second upper straight hole 254b. As the value of the diameter of the first column portion 122 in the horizontal direction is less than the value of the diameter of the second upper straight hole 254b, the first column portion 122 is slidable substantially in parallel with the Z direction in the second upper straight hole 254b.

The second column portion 132 of the second plunger 130 is inserted into the first lower straight hole 254c substantially parallel to the Z direction. The value of the diameter of the second column portion 132 in the horizontal direction is less than the value of the diameter of the first lower straight hole 254c. As the value of the diameter of the second column portion 132 in the horizontal direction is less than the value of the diameter of the first lower straight hole 254c, the second column portion 132 is slidable substantially in parallel with the Z direction in the first lower straight hole 254c. The value of the diameter of the second column portion 132 in the horizontal direction is equal to or greater than the value of the diameter of the second lower straight hole 254d in the horizontal direction. As the value of the diameter of the second column portion 132 in the horizontal direction is equal to or greater than the value of the diameter of the second lower straight hole 254d in the horizontal direction, the second column portion 132 can be prevented from exiting downward from the second lower straight hole 254d. The second distal end portion 134 of the second plunger 130 is inserted into the second lower straight hole 254d substantially parallel to the Z direction. The value of the diameter of the second distal end portion 134 in the horizontal direction is less than the value of the diameter of the second lower straight hole 254d. As the value of the diameter of the second distal end portion 134 in the horizontal direction is less than the value of the diameter of the second lower straight hole 254d, the second distal end portion 134 is slidable substantially in parallel with the Z direction in the second lower straight hole 254d. In the state shown in FIG. 2, the tapered portion 136 is caught in the second lower straight hole 254d.

In the state shown in FIG. 2, the lower end portion of the barrel 110 is held by the first lower straight hole 254c. For example, the value of the diameter of the lower end portion of the barrel 110 in the horizontal direction is relatively close to and 90% or more and less than 100% of the value of the diameter of the first lower straight hole 254c in the horizontal direction. In comparison with the case where the pin plate 230 is not provided, the barrel 110 can be, therefore, held substantially at the center of the straight hole 252 in the pin block 210 so that the probe 100 can be restrained from inclining in the pin block 210. The first column portion 122 of the first plunger 120 is held by the second upper straight hole 254b. For example, the value of the diameter of the first column portion 122 in the horizontal direction is relatively close to and 90% or more and less than 100% of the value of the diameter of the second upper straight hole 254b in the horizontal direction. In comparison with the case where the insulate plate 220 is not provided, the barrel 110 can be, therefore, held substantially at the center of the straight hole 252 in the pin block 210 so that the probe 100 can be restrained from inclining in the pin block 210. The second distal end portion 134 of the second plunger 130 is held by the second lower straight hole 254d. For example, the value of the diameter of the second distal end portion 134 in the horizontal direction is relatively close to and 85% or more and less than 100% of the value of the diameter of the second lower straight hole 254d in the horizontal direction. In comparison with the case where the pin plate 230 is not provided, the barrel 110 can be, therefore, held in the pin block 210 so that the probe 100 can be restrained from exiting from the pin block 210. As the lower end portion of the barrel 110, the first plunger 120, and the second plunger 130 are held, the lower end portion of the barrel 110 can be restrained from snagging at the step of the through hole 250 between the center straight hole 252 and the first lower straight hole 254c.

The floating plate 300 is disposed above the insulate plate 220. The floating plate 300 defines an opening 310. A bottom hole 312 is provided at the bottom portion of the opening 310. The bottom hole 312 extends through the floating plate 300 substantially parallel to the Z direction at the bottom portion of the opening 310. The object under inspection 20 is disposed inside the opening 310 with the first electrode 22 of the object under inspection 20 disposed inside the bottom hole 312.

In the state shown in FIGS. 1 and 2, the first distal end portion 124 of the first plunger 120 falls downward from the bottom hole 312. The value of the diameter of the first column portion 122 of the first plunger 120 in the horizontal direction is less than the value of the bottom hole 312 in the horizontal direction. Accordingly, the first distal end portion 124 of the first plunger 120 can be inserted into the bottom hole 312 when the first distal end portion 124 of the first plunger 120 and the first electrode 22 of the object under inspection 20 are in contact with each other.

The upper guide pin 410 includes an upper wide portion 412 and an upper narrow portion 414. The lower end portion of the upper wide portion 412 is inserted into the upper wide hole 262 provided in the insulate plate 220 substantially in parallel with the Z direction. The upper end portion of the upper wide portion 412 protrudes upward from the upper end of the upper wide hole 262. The upper narrow portion 414 extends downward from the lower end of the upper wide portion 412. The value of the diameter of the upper narrow portion 414 in the horizontal direction is less than the value of the diameter of the upper wide portion 412 in the horizontal direction. The upper narrow portion 414 is inserted into the first narrow hole 264 provided in the pin block 210 substantially parallel to the Z direction. The first narrow hole 264 extends through the pin block 210 substantially parallel to the Z direction. The value of the diameter of the first narrow hole 264 in the horizontal direction is less than the value of the diameter of the upper wide hole 262 in the horizontal direction. The upper wide portion 412 and the upper narrow portion 414 may have a cylindrical shape or a prismatic shape.

The lower guide pin 420 includes a lower wide portion 422 and a lower narrow portion 424. The upper end portion of the lower wide portion 422 is inserted into the lower wide hole 266 provided in the pin plate 230 substantially parallel to the Z direction. The lower end portion of the lower wide portion 422 protrudes downward from the lower end of the lower wide hole 266. The lower narrow portion 424 extends upward from the upper end of the lower wide portion 422. The value of the diameter of the lower narrow portion 424 in the horizontal direction is less than the value of the diameter of the lower wide portion 422 in the horizontal direction. The lower narrow portion 424 is inserted into the second narrow hole 268 provided in the pin block 210 substantially parallel to the Z direction. The second narrow hole 268 extends through the pin block 210 substantially parallel to the Z direction. The value of the diameter of the second narrow hole 268 in the horizontal direction is less than the value of the diameter of the lower wide hole 266 in the horizontal direction. The lower wide portion 422 and the lower narrow portion 424 may have a cylindrical shape or a prismatic shape.

Next, an example of a method of manufacturing the socket 10 according to the embodiment will be described with reference to FIG. 2 and, as necessary, with reference to FIG. 1. In this example, the socket 10 is manufactured as follows.

First, the upper narrow portion 414 of the upper guide pin 410 is press-fitted into the first narrow hole 264 of the pin block 210. The lower narrow portion 424 of the lower guide pin 420 is press-fitted into the second narrow hole 268 of the pin block 210. Next, the pin block 210 and the insulate plate 220 are superimposed on each other. When the pin block 210 and the insulate plate 220 are superimposed on each other, the upper wide portion 412 of the upper guide pin 410 is inserted into the upper wide hole 262 of the insulate plate 220. Next, the pin block 210 and the insulate plate 220 are fixed to each other by a fastener such as a screw not illustrated. Next, the probe 100 is inserted into the through hole 250 from above the pin block 210 with the pin block 210 disposed above the insulate plate 220.

When the probe 100 is inserted into the through hole 250, the first column portion 122 of the first plunger 120 passes through the first upper tapered hole 256a and the second upper tapered hole 256b. Accordingly, the first column portion 122 can be easily inserted into the first upper straight hole 254a in comparison with the case where the value of the diameter of the through hole 250 in the horizontal direction decreases stepwise from the center straight hole 252 to the first upper straight hole 254a. The first column portion 122 can be easily inserted into the second upper straight hole 254b in comparison with the case where the value of the diameter of the through hole 250 in the horizontal direction decreases stepwise from the first upper straight hole 254a to the second upper straight hole 254b. However, the value of the diameter of the through hole 250 in the horizontal direction may decrease stepwise from the center straight hole 252 to the first upper straight hole 254a. Similarly, the value of the diameter of the through hole 250 in the horizontal direction may decrease stepwise from the first upper straight hole 254a to the second upper straight hole 254b.

Next, the pin plate 230 is superimposed on the surface of the pin block 210 opposite to the surface on which the insulate plate 220 is located. When the pin plate 230 is superimposed on the surface of the pin block 210 opposite to the surface on which the insulate plate 220 is located, the lower narrow portion 424 of the lower guide pin 420 is inserted into the lower wide hole 266 of the pin plate 230. Next, the pin block 210 and the pin plate 230 are fixed to each other by a fastener such as a screw not illustrated.

When the pin block 210 and the pin plate 230 are superimposed on each other, the end portion of the side of the barrel 110 where the second plunger 130 is located passes through the first lower tapered hole 256c. The second distal end portion 134 of the second plunger 130 passes through the second lower tapered hole 256d. Accordingly, the end portion of the side of the barrel 110 where the second plunger 130 is located can be easily inserted into the first lower straight hole 254c in comparison with the case where the value of the diameter of the through hole 250 in the horizontal direction decreases stepwise from the center straight hole 252 to the first lower straight hole 254c. The second distal end portion 134 can be easily inserted into the second lower straight hole 254d in comparison with the case where the value of the diameter of the through hole 250 in the horizontal direction decreases stepwise from the first lower straight hole 254c to the second lower straight hole 254d. However, the value of the diameter of the through hole 250 in the horizontal direction may decrease stepwise from the center straight hole 252 to the first lower straight hole 254c. The value of the diameter of the through hole 250 in the horizontal direction may decrease stepwise from the first lower straight hole 254c to the second lower straight hole 254d.

Next, the floating plate 300 is disposed above the insulate plate 220. When the floating plate 300 is disposed above the insulate plate 220, the upper end portion of the upper wide portion 412 of the upper guide pin 410 is inserted into the upper guide hole 314 provided on the lower surface of the floating plate 300 substantially parallel to the Z direction. As the upper end portion of the upper wide portion 412 is inserted into the upper guide hole 314 substantially parallel to the Z direction, the floating plate 300 can be guided to an appropriate position in the horizontal direction with respect to the support body 200.

As described above, the socket 10 is manufactured.

FIGS. 3 and 4 are diagrams for explaining an example of a method of electrically connecting the object under inspection 20 and the inspection substrate 30 to each other via the socket 10 according to the embodiment.

An example of a method of electrically connecting the object under inspection 20 and the inspection substrate 30 to each other via the socket 10 according to the embodiment will be described with reference to FIGS. 3 and 4 and, as necessary, with reference to FIG. 1.

First, as shown in FIG. 3, the support body 200 provided with the probe 100 is placed on the upper surface of the inspection substrate 30. When the support body 200 is placed on the upper surface of the inspection substrate 30, the lower end portion of the lower wide portion 422 of the lower guide pin 420 is inserted into the lower guide hole 34 provided in the inspection substrate 30 substantially parallel to the Z direction. As the lower end portion of the lower wide portion 422 is inserted into the lower guide hole 34 substantially parallel to the Z direction, the support body 200 can be guided to an appropriate position in the horizontal direction with respect to the inspection substrate 30. The object under inspection 20 is disposed in the opening 310 of the floating plate 300 with the lower end portion of the lower wide portion 422 inserted into the lower guide hole 34 substantially parallel to the Z direction.

In the state shown in FIG. 3, the unillustrated spring provided in the space inside the barrel 110 is compressed in the Z direction to generate preload. Specifically, the first distal end portion 124 of the first plunger 120 is released while being spaced apart downward from the first electrode 22 of the object under inspection 20. The inner side surface of the first upper tapered hole 256a receives the upper end portion of the barrel 110. The barrel 110 is pushed downward by a force received from the inner side surface of the first upper tapered hole 256a. As the barrel 110 is pushed downward, the upper end portion of the second column portion 132 enters the barrel 110 in the Z direction. As the upper end portion of the second column portion 132 enters the inside of the barrel 110 in the Z direction, the unillustrated spring provided in the space inside the barrel 110 is compressed in the Z direction. The barrel 110 and the first plunger 120 are integrally biased upward by the preload. The second plunger 130 is biased downward by the preload.

In the embodiment, when the preload is generated, the inner side surface of the first upper tapered hole 256a of the pin block 210 having higher rigidity than the insulate plate 220 is a receiving portion for receiving the upper end portion of the barrel 110. If the insulate plate 220 receives the upper end portion of the barrel 110, the warping of the insulate plate 220 caused by the force received from the upper end portion of the barrel 110 can be difficult to restrain. In the embodiment, on the other hand, the occurrence of warping of the insulate plate 220 caused by the force received from the upper end portion of the barrel 110 can be restrained. In the embodiment, therefore, the upper end portion of the barrel 110 can be pushed downward with a strong force in comparison with the case where the insulate plate 220 receives the upper end portion of the barrel 110. As the upper end portion of the barrel 110 is pushed downward with a strong force, the preload can be stably generated in the embodiment in comparison with the case where the insulate plate 220 receives the upper end portion of the barrel 110.

The preload the support body 200 receives increases as the number of probes 100 increases. In the embodiment, as described above, the inner side surface of the first upper tapered hole 256a of the pin block 210 having relatively high rigidity receives the upper end portion of the barrel 110. If the insulate plate 220 receives a relatively large number of the upper end portions of the barrels 110, the damage to the insulate plate 220 caused by the force received from the upper end portion of the barrel 110 can be difficult to restrain. In the embodiment, however, the occurrence of the damage to the insulate plate 220 can be restrained because the inner side surface of the first upper tapered hole 256a of the pin block 210 receives the upper end portion of the barrel 110. In the embodiment, therefore, more probes 100 can be easily provided in the support body 200 in comparison with the case where the insulate plate 220 receives the upper end portion of the barrel 110.

In the embodiment, when the preload occurs, the lower end portion of the barrel 110 is held by the first lower straight hole 254c. Accordingly, the lower end portion of the barrel 110 can be restrained from snagging at the step of the through hole 250 between the center straight hole 252 and the first lower straight hole 254c in comparison with the case where the lower end portion of the barrel 110 is not held.

Next, as shown in FIG. 4, as the floating plate 300 is pushed downward by a semiconductor inspection device such as a handler not illustrated, the upper surface of the insulate plate 220 and the lower surface of the floating plate 300 contact each other. When the upper surface of the insulate plate 220 and the lower surface of the floating plate 300 contact each other, the first distal end portion 124 of the first plunger 120 and the lower end portion of the first electrode 22 of the object under inspection 20 contact each other. The barrel 110 and the first plunger 120 are pushed downward by the first electrode 22. As the barrel 110 and the first plunger 120 are pushed downward by the first electrode 22, the upper end portion of the barrel 110 is physically spaced apart downward from the inner side surface of the first upper tapered hole 256a. The probe 100 is electrically insulated from the pin block 210. As the barrel 110 is pushed downward, the upper end portion of the second column portion 132 further goes toward the inside of the barrel 110 in the Z direction as compared with the state shown in FIG. 3. For this reason, the first plunger 120 is pushed toward the first electrode 22 and the second plunger 130 is pushed toward the second electrode 32 by the unillustrated spring provided in the space inside the barrel 110. As the first plunger 120 and the second plunger 130 are pushed against the first electrode 22 and the second electrode 32 respectively, the first electrode 22 and the second electrode 32 are electrically connected to each other via the probe 100.

In the state shown in FIG. 4, any portion of the barrel 110 is not in contact with the pin block 210. A hollow gap is provided between the outer side surface of the barrel 110 and the inner side surface of the center straight hole 252. A coaxial probe is configured by the hollow gap provided between the outer side surface of the barrel 110 and the inner side surface of the center straight hole 252. Accordingly, the high frequency characteristics of the socket 10 can be improved.

In the embodiment, as the upper end portion of the barrel 110 is physically spaced apart downward from the first upper tapered hole 256a, the upper end portion of the barrel 110 and the pin block 210 are electrically insulated from each other. For this reason, the embodiment does not need an insulator ring to electrically insulate the upper end portion of the barrel 110 from the pin block 210. In the embodiment, therefore, the assembly property and the maintainability of the socket 10 can be improved and the component cost and the manufacturing cost can be reduced in comparison with the case where the insulator ring is used.

Hitherto, the embodiment of the present invention has been described above with reference to the drawings, but these are examples of the present invention, and various configurations other than the description above can be adopted.

According to the present specification, a socket of the following aspect is provided.

### (Aspect 1)

In the aspect 1, the socket includes an elastic probe and a conductor through which the probe extends, and the conductor has a receiving portion to receive the probe.

The “conductor” corresponds to the “pin block” of the embodiment described above. The “receiving portion” corresponds to the “first upper tapered hole” of the embodiment described above.

According to the aspect described above, when the preload is generated, the receiving portion of the conductor can receive the probe. For this reason, the preload can be stably generated in the aspect described above.

### (Aspect 2)

In the aspect 2, the socket further includes an insulator that overlaps the conductor and holds a part of the probe.

The “insulator” corresponds to the “insulate plate” or “pin plate” of the embodiment described above.

According to the aspect described above, the probe can be held in the conductor and the probe can be restrained from exiting from the conductor in comparison with the case where the insulator is not provided.

### (Aspect 3)

In the aspect 3, the insulator defines a tapered hole through which the probe extends.

The “tapered hole” corresponds to the “second upper tapered hole”, the “first lower tapered hole”, or the “second lower tapered hole” of the embodiment described above.

According to the aspect described above, the probe can be easily inserted into the insulator in comparison with the case where the value of the diameter of the through hole of the insulator for passage of the probe decreases stepwise in the portion where the tapered hole is located.

### (Aspect 4)

In the aspect 4, the probe has a barrel and two plungers provided at both end portions of the barrel, and the barrel and one of the two plungers are integrated.

The “two plungers” correspond to the “first plunger” and the “second plunger” of the embodiment described above.

According to the aspect described above, the electrical resistance of the probe can be easily reduced in comparison with the case where both of the two plungers are movable with respect to the barrel.

This application claims priority based on Japanese Patent Application No. 2022-141603, filed on Sep. 6, 2022, the entire disclosure of which is incorporated herein by reference.

### REFERENCE SIGNS LIST

10 socket, 20 object under inspection, 22 first electrode, 30 inspection substrate, 32 second electrode, 34 lower guide hole, 100 probe, 110 barrel, 120 first plunger, 122 first column portion, 124 first distal end portion, 130 second plunger, 132 second column portion, 134 second distal end portion, 136 tapered portion, 200 support body, 210 pin block, 220 insulate plate, 230 pin plate, 250 through hole, 252 center straight hole, 254a first upper straight hole, 254b second upper straight hole, 254c first lower straight hole, 254d second lower straight hole, 256a first upper tapered hole, 256b second upper tapered hole, 256c first lower tapered hole, 256d second lower tapered hole, 262 upper wide hole, 264 first narrow hole, 266 lower wide hole, 268 second narrow hole, 300 floating plate, 310 opening 312 bottom hole, 314 upper guide hole, 410 upper guide pin, 412 upper wide portion, 414 upper narrow portion, 420 lower guide pin, 422 lower wide portion, 424 lower narrow portion

1. A socket comprising:
an elastic probe; and
a conductor through which the probe extends,
wherein the conductor has a receiving portion for receiving the probe.

2. The socket according to claim 1, further comprising:
an insulator that overlaps the conductor and holds a part of the probe.

3. The socket according to claim 2,
wherein the insulator defines a tapered hole through which the probe extends.

4. The socket according to claim 1,
wherein the probe has a barrel and two plungers provided at both end portions of the barrel, and
the barrel and one of the two plungers are integrated.
